(19) United States
(12) Patent Application Publication
(10) Pub. No.: US 2003/0181023 A1
(43) Pub. Date: Sep. 25, 2003

(54) Method of processing silicon single crystal ingot

(76) Inventor: Masanori Kimura, Gunma (JP)

Correspondence Address: HOGAN & HARTSON L.L.P., 500 S. GRAND AVENUE, SUITE 1900, LOS ANGELES, CA, 90071-2611, US

(21) Appl. No.: 10/362,947

(22) PCT Filed: Aug. 23, 2001
(86) PCT No.: PCT/JP01/07226

(30) Foreign Application Priority Data
Mar. 7, 2002 (JP) 2000-257437

(51) Int. Cl. H01L 21/301; H01L 21/46; H01L 21/78

(52) U.S. Cl. 438/460

(57) ABSTRACT

The present invention provides a method for processing a silicon single crystal ingot in which the silicon single crystal ingot is sliced into wafers, wherein the single crystal ingot is divided by cutting along a direction parallel to an axial line of the ingot before the single crystal ingot is sliced into wafers, and then the divided ingots are sliced into wafers having a desired thickness. Thus, there is provided a processing method that makes it possible to slice a silicon single crystal ingot having a large diameter into thin wafers at a high yield without thickening unnecessarily a thickness of a wafer upon slicing.

### TECHNICAL FIELD The present invention relates to a processing method used at the time of slicing a silicon single crystal ingot into wafers.

### BACKGROUND ART

Currently, when a silicon single crystal ingot is sliced into wafers for the production of semiconductor integrated circuits or for solar cells, single crystal ingots grown by the CZ method (Czochralski method) or the FZ method (floating zone melting method) are usually used in many cases. These single crystal ingots are produced in a cylindrical shape. And sidewalls of these single crystal ingots are ground to produce cylinders having a predetermined diameter, and these cylindrical ingots are sliced along a direction perpendicular to the axial line thereof (center axis) or along a direction having a certain angle intentionally with respect to the axial line to obtain wafers.

Further, at the time of the slicing into wafers, the slicing is performed by using a wire saw, an inner diameter slicer or the like.

As shown in FIG. 4, the wire saw is an apparatus consisting of a thin metal wire 5, which is wound around guide rollers 4 several hundreds of times with constant intervals with respect to the direction of the rotation axis of the guide rollers 4, and reciprocally moved by reciprocating rotational movement of the guide rollers 4, wherein a silicon single crystal ingot 1 adhered to a backplate 3 is pressed against the wire 5 between the guide rollers 4, 4 and sliced with supplying slurry for grinding. Therefore, if the wire saw is used, it is possible to slice simultaneously one single crystal ingot into many wafers.

On the other hand, the inner diameter slicer (not shown) is an apparatus wherein by using a doughnut-shaped cutting blade in which abrasive grains are stuck in the direction of the inner diameter of an opening, a single crystal ingot is placed in the opening and sliced into wafers one by one. Tension is applied to the outer peripheral portion of the cutting blade so that the cutting blade should not bend, and it is characterized in that the blade is hardly deformed upon slicing and the blade can be easily carried straight along the cutting direction.

Since both of the wire saw and the inner diameter slicer are designed so that the load applied on a single crystal ingot should become small, it is possible to slice a wafer having a thickness of around 500 μm from a single crystal ingot having a diameter of 150 mm (6 inches) without breakage of the wafer.

However, substrates for semiconductor integrated circuits and substrates for solar cells both have a thickness of about 200 μm for finally used portions, and therefore it has been considered ideally that the production should be performed by using a silicon wafer having a thickness of about 200 to 300 μm as a starting material. In fact, when a single crystal ingot has a small diameter such as 100 mm (4 inches) or less, it is possible to slice it into thin wafers having a thickness of 200 to 300 μm. However, if it has a large diameter of 200 mm (8 inches) or more, or even 300 mm (12 inches) or more, it becomes difficult to slice it in the aforementioned thickness since breakage of wafer is caused due to the problem of strength, and thus the production yield of the wafers becomes extremely low. Incidentally, it is considered generally that, in case of a wafer having a diameter of 200 mm, a thickness of 800 μm or more is required, and in case of a wafer having a diameter of 300 mm, a thickness of 1000 μm or more is required.

For both of semiconductor integrated circuits and solar cells, it is important to reduce the production cost of the substrates therefor as much as possible, and this requirement has been satisfied by making diameter of a single crystal ingot increasingly larger. However, in order to slice a single crystal ingot having a large diameter without causing breakage, the thickness of wafer must be made larger for obtaining strength, and therefore yield of wafers obtained by slicing of a single crystal ingot has been decreased. Therefore, there has been being desired a technique that makes it possible to slice a single crystal ingot at a minimum of thickness into wafers as many as possible, even if diameter of a single crystal ingot becomes larger.

### DISCLOSURE OF THE INVENTION

Thus, the present invention has been accomplished in view of the aforementioned problem, and its major object is to provide a processing method that makes it possible to slice a silicon single crystal ingot having a large diameter into wafers at a high yield by making a thickness of a wafer upon slicing as small as possible without thickening unnecessarily the thickness.

In order to achieve the aforementioned object, a method according to the present invention is a processing method in which a silicon single crystal ingot is sliced into wafers, wherein the single crystal ingot is divided by cutting along a direction parallel to an axial line of the ingot before the single crystal ingot is sliced into wafers, and then the divided ingots are sliced into wafers having a desired thickness.

If before the single crystal ingot having a large diameter is sliced into wafers, the single crystal ingot is divided beforehand by cutting along a direction parallel to the axial line of the ingot so that an area of a cross section (also referred to as transverse cross sectional area) perpendicular to the axial line direction of the ingot should be reduced as described above, the ingot can be sliced into thin wafers as in the case of a single crystal ingot having a small diameter. That is, one single crystal ingot having a large diameter is cut into a plurality of divided ingots, then these divided ingots are sliced into wafers having a desired thickness, and thereby the ingots can be sliced into thin wafers without breakage due to the problem of strength. Therefore, when a single crystal ingot having a large diameter is sliced into wafers, it becomes unnecessary to slice into the excessive thick wafers in order to avoid breakage of the wafers, and thus improvement of the production yield of the wafers can be achieved.

In this case, the multiple divided ingots obtained by the division along the direction parallel to the axial line are preferably sliced simultaneously into wafers having a desired thickness.

If the multiple divided ingots obtained by the division through cutting along the direction parallel to the axial line are, for example, bundled into a shape of the original ingot by facing the cut faces, and then sliced into wafers having a desired thickness as described above, the multiple ingots once divided are returned into a substantially original state and sliced at one time, and thus the productivity is not decreased. Further, since the slicing conditions for the individual divided ingots are similar to a slicing condition of a single crystal ingot having a small diameter, the ingots can be sliced into thin wafers without causing breakage due to a problem of strength, and thus the yield of wafers can be improved.

In the present invention, the silicon single crystal ingot to be divided along the direction parallel to the axial line preferably has a diameter of 200 mm or more.

As for an ingot having a diameter of 200 mm or more, the thickness to be sliced conventionally must be 800 μm or more for slicing. The present invention has particular advantage that such an ingot having a large diameter can be divided, and sliced in a small thickness. Therefore, as an ingot has a larger diameter of 300 mm or more in future, the present invention will become more and more advantageous, because such an ingot can also be divided and sliced according to the present invention.

Further, the wafers are preferably sliced to have a thickness of 200 to 600 μm.

As described above, according to the present invention, a wafer having a thickness of 200 to 600 μm can be sliced from a single crystal ingot having a diameter of 200 mm or more without causing breakage of the wafer, thus the productivity of wafers can be improved, and high yield and cost reduction of wafers can be achieved.

As explained above, if the method of the present invention is used, thin wafers can be sliced from a silicon single crystal ingot having a large diameter with high yield.

### BRIEF EXPLANATION OF THE DRAWINGS

FIG. 1 is an explanatory view showing an example of a method for dividing a silicon single crystal ingot according to the present invention.

FIG. 2(a) to (c) are explanatory views showing an example of a slicing method according to the present invention using a wire saw.

FIG. 3 is a perspective view showing an example of a wafer sliced according to the present invention.

FIG. 4 is an explanatory view showing a conventional slicing method using a wire saw.

### BEST MODE FOR CARRYING OUT THE INVENTION

Hereafter, the present invention will be explained in detail.

The inventors of the present invention eagerly studied about a method of slicing a silicon single crystal ingot having a large diameter thinly. As a result, they noted that wafers need not be necessarily in a circular shape, and a single crystal having a small diameter could be sliced thinly without breakage due to a problem of strength, and investigated various conditions required for the slicing. Thus, they accomplished the present invention.

That is, the present invention is a processing method in which a silicon single crystal ingot is sliced into wafers, wherein the single crystal ingot is divided by cutting along a direction parallel to an axial line of the ingot before the single crystal ingot is sliced into wafers, and then the divided ingots are sliced into wafers having a desired thickness.

If a single crystal ingot is once divided by cutting along a direction parallel to an axial line of the ingot so that an area of a cross section (transverse cross sectional area) perpendicular to the axial line direction should be reduced as described above, the transverse cross sectional area can be similar to that of a single crystal ingot having a small diameter. Therefore, the ingot can be sliced into thin wafers without causing breakage of the wafers as in the case of a single crystal ingot having a small diameter.

In this case, the number of divided ingots obtained by the division along the direction parallel to the axial line of the ingot may be an arbitrary number of 2 or more, and it may be determined so that the divided ingots obtained by the division should have a transverse cross sectional area similar to that of a single crystal having a small diameter to be capable of slicing the divided ingots into wafers having a desired thickness without breakage of the wafers. Further, the ingot may not necessarily be divided uniformly, and sizes of the divided ingots can be adjusted depending on a combination of sizes of wafers.

Then, the step of slicing the divided ingots into wafers having a desired thickness is performed.

In this step, in order to simultaneously slice the multiple divided ingots obtained by cutting the single crystal ingot along the direction parallel to the axial line of the single crystal ingot, the multiple divided ingots are preferably put in parallel with a direction perpendicular to the moving direction of the wire or to the rotation direction of the inner diameter blade or bundled together, and then sliced into wafers having a desired thickness. Although individual divided ingots may of course be sliced one by one, it causes a reduction of the productivity.

When the slicing is performed with the wire or inner diameter blade, all divided ingots obtained by the division are arranged, adhered to a backplate, and then they may be sliced simultaneously or sliced in multiple times in consideration of the slicing speed and quality of the sliced faces.

Further, the multiple divided ingots obtained by the division may be bundled into a shape of the original ingot by facing the cut faces and then sliced. If the ingots are sliced as described above, the ingots once divided are returned into a substantially original state of one ingot and sliced at a time, and therefore the productivity is not reduced. Further, the bundled multiple ingots may be put in parallel and then sliced.

Moreover, since the transverse cross sectional areas of the individual divided ingots are similar to a transverse cross sectional area of a single crystal ingot having a small diameter, they can be sliced into thin wafers without causing breakage of the wafers due to a problem of strength and thus yield of the wafers can be improved.

In addition, the backplate may be adhered to outer surfaces or cut faces of the crystals.

The method for processing a silicon single crystal ingot according to the present invention is preferably applied to a single crystal ingot having a diameter of 200 mm or more as an ingot to be divided along the direction parallel to the axial line. In this case, the ingot can be sliced so that the sliced wafers should have a thickness of 200 to 600 μm without breakage of the wafers. Thus, the yield of the wafer can be improved, and marked reduction of the cost can be attained.

The thickness of slicing is defined to be 200 μm or more, because such a thickness is a thickness required for actual fabrication of devices and so forth. The thickness of 600 μm is a sufficient thickness therefor, and the transverse cross sectional area may be similar to that of an ingot having a diameter of 150 mm (6 inches).

The present invention will be explained in more detail hereafter. However, the present invention is not limited to the following explanations.

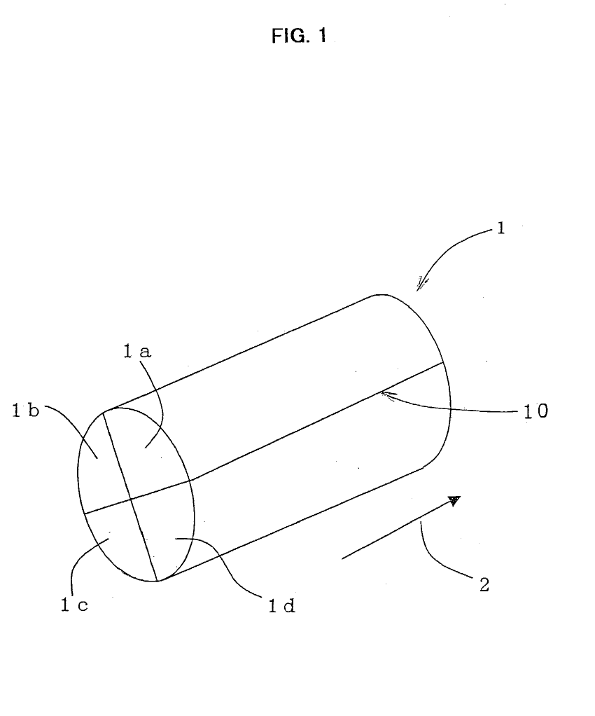

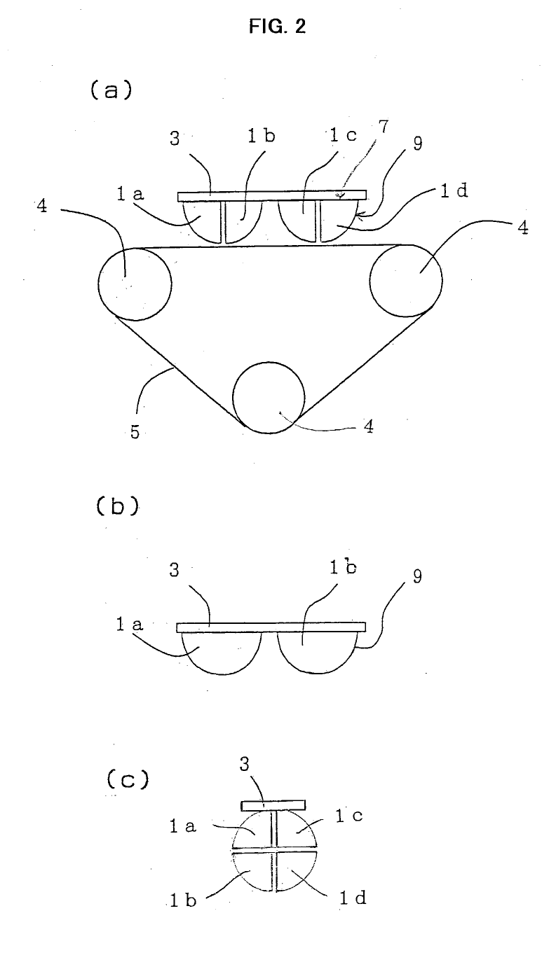

FIG. 1 is an explanatory view showing a method for dividing silicon single crystal ingot by cutting according to the present invention and FIG. 2 is explanatory views showing a slicing method of wafers.

As shown in FIG. 1, for example, a silicon single crystal ingot 1 is vertically divided along dividing lines 10 parallel to the direction of an axial line 2 of the ingot into four pieces to obtain four divided ingots 1a, 1b, 1c and 1d. Then, as shown in FIG. 2(a), the divided ingots 1a, 1b, 1c and 1d are arranged, adhered and fixed to a backplate 3 with adhesive, and then set on a wire saw. Thereafter, these divided ingots 1a, 1b, 1c and 1d are pressed against a wire 5 which moves reciprocally by rotating guide rollers 4 to slice them into wafers.

When the slicing is performed with the wire saw, all divided ingots which are divided as shown in FIG. 2(a) [division into four pieces] or FIG. 2(b) [division into two pieces] are arranged and adhered to the backplate 3, and then they may be sliced simultaneously or sliced in multiple times in consideration of the slicing speed and quality of sliced faces. Further, four of the divided ingots 1a, 1b, 1c and 1d which are divided as shown in FIG. 2(c) may be bundled into the original state of one ingot by putting them together at the cut faces, and then sliced. The backplate 3 may be adhered to outer surfaces 9 or cut faces 7 of the crystals.

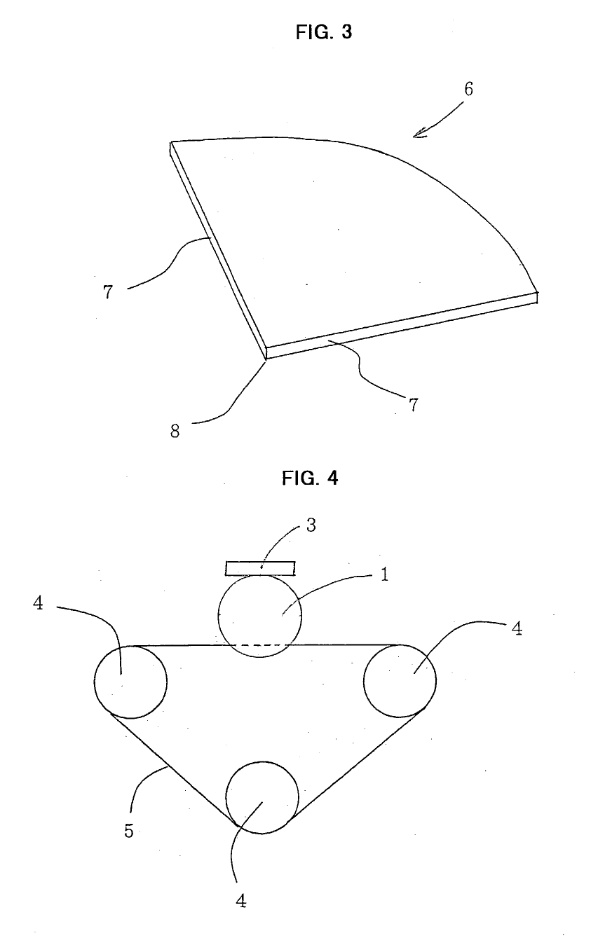

An example of a wafer obtained by slicing a divided ingot is shown in FIG. 3. Since the sliced wafer 6 tends to generate a crack at the cut faces 7 or cut face crossing point 8 at which cut faces cross each other, it is preferable to subject them to chamfering appropriately. Further, when the cut face 7 is used as a standard plane for positioning of the wafer in production processes of semiconductor integrated circuits and solar cells, it has been desirably polished with high precision.

When the wafer 6 having a plane orientation of <100> is obtained, the division can be performed so that the cut face 7 should be (110) of a cleavage plane to increase strength of the wafer 6.

Hereafter, the present invention will be specifically explained with reference to the following example of the present invention and comparative example. However, the present invention is not limited to these.

### EXAMPLE 1

A silicon single crystal ingot having an orientation of <100> and a diameter of 200 mm, which was grown by the CZ method, was divided equally into four pieces along a direction parallel to the axial line of the ingot. The divided ingots obtained by the division into four pieces were set on a wire saw as shown in FIG. 2(a) and sliced. The slicing was performed as a setting of a slicing thickness was changed from 800 μm to 100 μm with an interval of 100 μm. Percentages of the numbers of wafers sliced without breakage among 800 pieces of the sliced wafers (corresponding to 200 pieces of wafers having a diameter of 200 mm) for each setting of a slicing thickness are shown in Table 1 as the yield.

### COMPARATIVE EXAMPLE 1

A silicon single crystal ingot was sliced by using a wire saw under the same conditions as Example 1 except that the ingot was not divided and the setting of a slicing thickness was changed from 800 μm to 300 μm with an interval of 100 μm. Percentages of the numbers of wafers sliced without breakage among 200 pieces of sliced wafers are also shown in Table 1.

TABLE 1

| | Slicing thickness | |
|---|---|---|
| | (μm) | Yield (%) |
| Example 1 | 800 | 100 |
| | 700 | 100 |
| | 600 | 100 |
| | 500 | 100 |
| | 400 | 100 |
| | 300 | 98 |
| | 200 | 86 |
| | 100 | 61 |
| Comparative | 800 | 99 |
| Example 1 | 700 | 88 |
| | 600 | 62 |
| | 500 | 45 |
| | 400 | 33 |
| | 300 | 24 |

It was found that, when the method for processing a crystal according to the present invention was used, sufficient yield could be obtained for a wafer thickness of 200 μm or more. In addition, as seen in the comparative example, it was found that the conventional method may be used when the thickness is 700 μm or more. However, when the thickness became 600 μm or less, the slicing yield was markedly reduced in the conventional method.

The present invention is not limited to the embodiments described above. The above-described embodiments are mere examples, and those having the substantially same structure as that described in the appended claims and those providing similar functions and advantages are all included in the scope of the present invention.

1. A method for processing a silicon single crystal ingot in which the silicon single crystal ingot is sliced into wafers, wherein the single crystal ingot is divided by cutting along a direction parallel to an axial line of the ingot before the single crystal ingot is sliced into wafers, and then the divided ingots are sliced into wafers having a desired thickness.

2. The method for processing a silicon single crystal ingot according to claim 1, wherein the multiple divided ingots obtained by the division along the direction parallel to the axial line are simultaneously sliced into wafers having a desired thickness.

3. The method for processing a silicon single crystal ingot according to claim 1 or 2, wherein the silicon single crystal ingot to be divided along the direction parallel to the axial line has a diameter of 200 mm or more.

4. The method for processing a silicon single crystal ingot according to any one of claims 1 to 3, wherein the wafers are sliced to have a thickness of 200 to 600 μm.
